(19) United States
(12) Patent Application Publication
(10) Pub. No.: US 2015/0349233 A1
(43) Pub. Date: Dec. 3, 2015

(54) CARRIER ELEMENT AND MODULE

(71) Applicant: O-FLEXX TECHNOLOGIES GMBH, Duisburg (DE)

(72) Inventors: Gerhard SPAN, WATTENS (AT); Christian VITEK, Boos-Reichau (DE); Stefan HOPPE, Dorsten (DE)

(21) Appl. No.: 14/761,278

(22) PCT Filed: Mar. 5, 2014
(86) PCT No.: PCT/EP2014/054286

§ 371 Date: Jul. 15, 2015

(30) Foreign Application Priority Data
Mar. 6, 2013 (DE) 10 2013 102 240.5

(51) Int. Cl. H01L 35/32

(52) U.S. Cl. CPC H01L 35/32

(57) ABSTRACT

A carrier element includes a coupling to a heat source, a coupling to a heat sink, and a thermoelectric thin-layer element with a hot side and a cold side, arranged on the carrier element between the coupling to the heat source and the coupling to the heat sink. The hot side is in thermally conductive contact with the coupling to the heat source, and the cold side is in thermally conductive contact with the coupling to the heat sink. To avoid damaging tensile and shear stresses in the thermoelectric thin-layer element, especially in the thermoelectrically active material, while ensuring good thermal coupling at the same time, at least one elastic and/or flexible compensating section of the carrier element is set up between the coupling to the heat source and the coupling to the heat sink in such a way that it compensates for the difference between the expansions of the heat source and those of the heat sink by a change of shape of the compensating section.

The invention pertains to a carrier element comprising a coupling to a heat source and a coupling to a heat sink as well as a thermoelectric thin-layer element arranged between the coupling to the heat source and the coupling to the heat sink. The invention also pertains to a module with several carrier elements.

Heat can be converted directly to electrical energy by means of a thermoelectric element operated as a generator. For this purpose, variously doped semiconductor materials are preferably used, which make it possible to increase the efficiency significantly beyond that of thermoelectric elements made with two different metals connected together at one end. Commonly used semiconductor materials are Bi₂Te₃, PbTe, SiGe, BiSb, and FeSi₂. To generate sufficiently high voltages, a plurality of thermoelectric pairs are usually connected electrically in series in a single thermoelectric element.

The way in which a thermoelectric element works is based on the thermoelectric effect, referred to in the following as the “Seebeck effect”. The Seebeck effect is the name given to the occurrence of an electrical voltage between two points of an electrical conductor or semiconductor which are at different temperatures. The voltage thus produced is determined by:

U_{Seebeck}=α×ΔT,

where

ΔT=the temperature difference between two points of the conductor/semiconductor at the contact points; and

α=the Seebeck coefficient.

Conventional thermoelectric elements consist of several blocks of thermoelectrically active semiconductor material, which are electrically connected to each other by metal bridges, alternating between top and bottom. At the same time, the metal bridges form the thermal contact surfaces and are insulated by a ceramic plate resting on top.

In addition, thermoelectric thin-layer elements are also known from the prior art:

A thermoelectric thin-layer element with a support structure, on which several thermobars of a first conductive material and several thermobars of a second conductive material are applied, is known from DE 10 2006 031 164 A1, wherein the first and second conductive materials have different conductivities, and the thermobars are connected electrically to each other in such a way that two thermobars form a thermoelectric pair, wherein all of the thermobars of the first and second conductive materials are arranged next to each other on the support structure. The cold side of the thermoelectric thin-layer element is located on one side of the electrically conductive first and second materials, and the hot side is located on the opposite side of the electrically conductive first and second materials.

A thermoelectric thin-layer element, finally, is known from DE 101 22 679 A1, which comprises a flexible substrate material, on which thin-layer thermoelectric pairs are applied. The thin-layer thermoelectric pairs are formed out of a material combination of two different materials, wherein the first and the second materials are set up and thermally coupled to each other in such a way that together they form a thermoelectric pair. The two materials are printed on the flexible film or deposited by means of conventional deposition methods. Strips of nickel, for example, as the first material and strips of chromium as the second material are arranged next to each other, wherein the ends of the strips of each pair are connected electrically to each other by a connecting structure of the second material. The connected strips thus form a series circuit consisting of several thermoelectric pairs occupying a small surface area. The large number of thin-layer thermoelectric pairs leads to a high output voltage of the thermoelectric element. The electrical connecting structures on the one side of the thermoelectric thin-layer element form its hot side, whereas the connecting structures on the opposite of the thermoelectric thin-layer element form its cold side, wherein the hot side is connected to a heat source by a coupling element, the cold side to a heat sink.

A heat-exchanger for a thermoelectric thin-layer element with a hot side and a cold side is known from DE 10 2008 032 856 A1, wherein the flexible thin-layer element is clamped on the hot side between two profiled sections of a coupling element and on the cold side between two profiled sections of a heat sink. In the exemplary embodiment described here, the heat sink is formed by the profiled clamping sections, on which cooling ribs extending outward from the clamping sections are arranged.

Good thermoelectric materials are brittle, and the only force to which they can be subjected mechanically is pressure. Tensile and shear stresses therefore do not lead to plastic deformation but rather to the fracture of the thermoelectrically active material. So that the thermoelectrically active materials of conventional thermoelectric elements can be protected as effectively as possible from exposure to any force other than pressure in spite of the difference between the expansion of the heat source and that of the heat sink, the ceramic plate on the hot side is coupled to the heat source in such a way that it is free to slide. The low thermal resistance between the heat source and the ceramic plate, which is necessary to obtain a thermoelectric element of high efficiency, requires in principle, however, a very high compressive force, but because the plate must be free to slide to compensate for the different degrees of expansion, such high compression cannot be used. To find the best possible compromise in this respect, the frictional bond must be uniform across the entire surface of the slidingly supported ceramic plate; however, a frictional bond of this type can be realized only with extremely great manufacturing effort, which so far it has not been possible to automate.

Against the background of this prior art, the invention is based on the goal of proposing a carrier element with a thermoelectric thin-layer element arranged on the carrier element, by means of which damaging tensile and shear stresses in the thermoelectric thin-layer element, especially in the thermoelectrically active material, can be avoided, while good thermal coupling to a heat source and heat sink is nevertheless ensured.

This goal is achieved in a carrier element of the type indicated above in that at least one elastic and/or flexible compensating section of the carrier element is installed between the coupling to the heat source and the coupling to the heat sink in such a way that it compensates for differences in the expansions of the heat source and the heat sink through the change in shape of the compensating section.

The change in the shape of the compensating section is able to compensate completely for the difference between the expansion of the heat source and that of the heat sink; as result, the other areas of the carrier element cannot be deformed by the different degrees of thermal expansion. In particular, the thermoelectrically active material, which is sensitive to shear stresses, is arranged in these other areas and is thus not subjected to any shear.

The compensating section provided according to the invention makes it possible for the carrier element to be coupled to the heat source and the heat sink by means of a permanent material bond. A permanent material bond eliminates the need to apply large compressive forces between the heat source or heat sink and the coupling of the carrier element to the heat source or heat sink in order to achieve low thermal resistance. In addition, a permanent bond means that wider manufacturing tolerances can be accepted for both the carrier element and the heat source or heat sink. Any manufacturing tolerances which may occur can be compensated by means of the adhesive, for example, or by the solder used to produce the permanent bond.

To achieve a long life cycle, each compensating section preferably comprises linear-elastic behavior.

To equalize the stresses caused by the different expansions of the heat source and heat sink, the compensating section can comprise elevations and/or depressions produced by embossing.

Preferably, however, the compensating section comprises a nubby structure with a two-dimensional arrangement of elevations and depressions. A nubby structure of this type makes it possible for compensating movements to occur in response to forces acting in any direction in the compensating section.

The elastic compensating section can also be configured as an elastic bellows—also called a folding bellows—functioning in the same way as an expansion joint. Each bellows can be provided with at least one, preferably several, slots, arranged transversely to the lines along which the folds of the bellows extend. Insofar as the folds of the bellows are at a right angle to the primary direction in which the heat source expands, expansions of the heat source versus the heat sink perpendicular to the main expansion direction are compensated by the slots. Like the compensating section provided with the nubby structure, the slotted bellows also allows compensating movements to occur in response to forces acting in any spatial direction in the compensating section.

The elastic compensating section can be made of the same material as the other areas of the carrier element. Metals, for example, can be used as material for the carrier element and the embossed elastic compensation section, especially metals which can effectively withstand aggressive media and high temperatures. In contrast to the other areas of the carrier element, however, the elastic compensating section can also be made of soft material such as industrial fabric or of elastomeric material.

The thermoelectric thin-layer element comprises a substrate and thermoelectrically active material, which is applied to the substrate. The thermoelectrically active material comprises a layer thickness of no more than 150 μm.

The substrate is electrically insulating to prevent areas of thermoelectrically active material, separated from each other and alternating with each other on the hot and cold side of the thin-layer element, from being connected electrically to each other by the metalized areas applied to the substrate. To prevent heat from flowing from the hot side to the cold side through the substrate, the material of the substrate comprises low thermal conductivity. The areas of thermoelectrically active material are preferably connected in series.

The substrate can be flexible; for example, it can be in the form of polyimide film. The substrate formed as a film is preferably in the form of a strip with the hot and cold sides on opposite long sides of the strip. The flexible film can also be arranged on, and attached to, the carrier element so that it either completely covers or partially overlaps the compensating section. When the film is arranged on, and attached to, the carrier element, however, care must be taken to ensure that no thermoelectrically active material is present in the area above the compensating section.

The substrate can also consist of a rigid material. In this case, each compensating section is located in an area of the carrier element which does not overlap the substrate. Otherwise, the rigid material of the substrate would interfere with the elastic and/or flexible behavior of the compensating section.

The thermoelectric thin-layer element is connected to a surface, in particular to a flat surface, of the carrier element by a permanent material bond, which can be achieved by means of adhesive bonding or soldering. To facilitate the soldering, the back of the substrate to be soldered can be metalized.

In a preferred embodiment of the invention, the carrier element comprises a plate, onto which the thermoelectric thin-layer element is applied. Such flat surfaces are especially well adapted to the attachment of thermoelectric thin-layer elements. In addition, the compensating section can be produced directly in a relatively thin plate, in particular by embossing.

Insofar as a thermoelectric thin-layer element with a flexible substrate is applied to the carrier element, the plate and the substrate can comprise slots which are aligned with each other in the overlapping areas; these slots will then absorb the stresses which occur in the overlapping areas. In particular, the slots in the plate and in the substrate extend for this purpose in a direction perpendicular to the main direction in which the heat source expands. If the compensating section is configured as a bellows, the slots will be perpendicular to its folds.

For a preferably permanently bonded coupling of the carrier element to the heat source and the heat sink, connecting elements are arranged on the plate; these elements extend at an angle, especially at a right angle, to the plane of the plate. Insofar as the connecting elements are configured as tabs, they can be produced by bending over the opposite long sides of the plate. To couple the carrier element to tubular heat sources or heat sinks, the connecting elements are preferably designed as sleeves. The size of the contact area between the sleeve and the tube leads to very good thermal coupling. Insofar as the sleeve passes through the plate, the tube of the heat sink or heat source can be guided through the sleeve. To achieve uniform thermal coupling or decoupling, several connecting elements are arranged uniformly along the hot and cold sides of the thermoelectric thin-layer element. If only one connecting element is arranged on the hot side and only one connecting element on the cold side of the thermoelectric thin-layer element, the long dimension of the connecting element in the plane of the plate will be approximately the same as the long dimension of the thermoelectric thin-layer element along the hot and cold sides.

To improve the conduction of heat to the heat source and/or the heat sink, certain areas of the carrier element can be provided with a functional layer with higher thermal conductivity than the carrier element. The carrier element consists, for example, of high-grade steel, and the functional layer consists of copper. The functional layer is applied in particular to the area where the coupling to the heat source or heat sink is made and in the area of the overlap between the carrier element and the thermoelectric thin-layer element. In the area where the thermo-electrically active material is located, the functional layer is interrupted to prevent heat from being lost by flowing between the cold and hot sides of the thermoelectric element mounted along with its substrate on the functional layer. The interruption of the functional layer can be realized as a gap.

Depending on the thermal conductivity of the carrier element, additional decoupling of the heat source from the heat sink can be achieved by dividing the carrier element, especially its plate, by at least one slot, wherein a first part of the plate on one side of the slot is connected in thermally conductive fashion to the heat source, and a second part of the plate on the opposite side of the slot is connected to the heat sink in thermally conductive fashion.

For reasons of stability, the first and second parts of the plate can be connected to each other by at least one, preferably by several, narrow slot-bridging webs, i.e., narrow in comparison to the long dimension of the slot. Only small amounts of parasitic heat-loss flows pass from the hot side to the cold side via webs which are narrow in comparison to the length of the slot. If a functional layer is provided on the carrier element, it is interrupted in the area of these webs.

If such webs are provided, the base of the web on the first and/or second part of the plate can be configured as a compensating section. To give the base of the web elastic and/or flexible properties, the thickness of the material and/or the properties of the material of the web can be different that the thickness and/or properties present in the other areas of the carrier element. The thermoelectrically active material of the thin-layer element is located exclusively in an area which, in relation to the plate surface, is above the slot, wherein the metalized areas of the thin-layer element are thermally connected alternately on the hot side to the first part and on the cold side to the second part of the plate or functional layer. The web bases acting as compensating sections define a bending line on each side of the thermoelectrically active material to absorb the different expansions of the heat source and heat sink. The bending lines extend along the transition areas between the thermoelectrically active material and the metalized contact areas on the flexible substrate. In this transition area, the substrate can follow a rotational movement around the bending line of the carrier element without the thermoelectrically active material being subjected to shear forces. If the slot has a width of 4 mm, for example, and the thermoelectrically active material extends 2 mm in the direction of the slot width, then, if the thermoelectrically active material is arranged centrally in the slot, a transition area of 1 mm in each case is present on both sides. The bending line extends through this transition area.

In an advantageous embodiment of the invention, the heat sink and/or the heat source comprises at least one tube for a heat transfer medium, to which tube the carrier element is connected. As a result, the waste heat from a heating circuit, for example, can be used in one or more thermoelectric thin-layer elements.

In that the tubes of the heat source or heat sink and the sleeve-like connecting elements which hold them are perpendicular to the plate of the carrier element, the heat flux in the thermoelectric thin-layer elements flows transversely to the direction in which the heat-transfer medium is flowing in each tube. As a result, a temperature drop along the thermoelectric thin-layer element is avoided, which results in a significant increase in output. In addition, an arrangement of the carrier elements transversely to the long dimension of the heat source and heat sink allows the compensating section in the web base to function properly.

If each tube of a heat sink and/or heat source is connected to several carrier elements, a cascade of thermoelectric thin-layer elements can be combined into a module. Some of the thin-layer elements applied to the several carrier elements can be connected electrically in series or in parallel as a function of the temperature curve along the tubes.

In one embodiment of the invention, the plate of the carrier element is ring-shaped and divided by a slot into concentric circular rings. A carrier element shaped in this way makes it possible for it to be connected to an elongated, in particular a tubular, heat source and heat sink, both of which extend in a direction perpendicular to the ring-shaped plate. The connecting elements for the coupling to the heat source and heat sink also extend in a direction parallel to the plane of the plate.

The invention is explained in greater detail below on the basis of the figures:

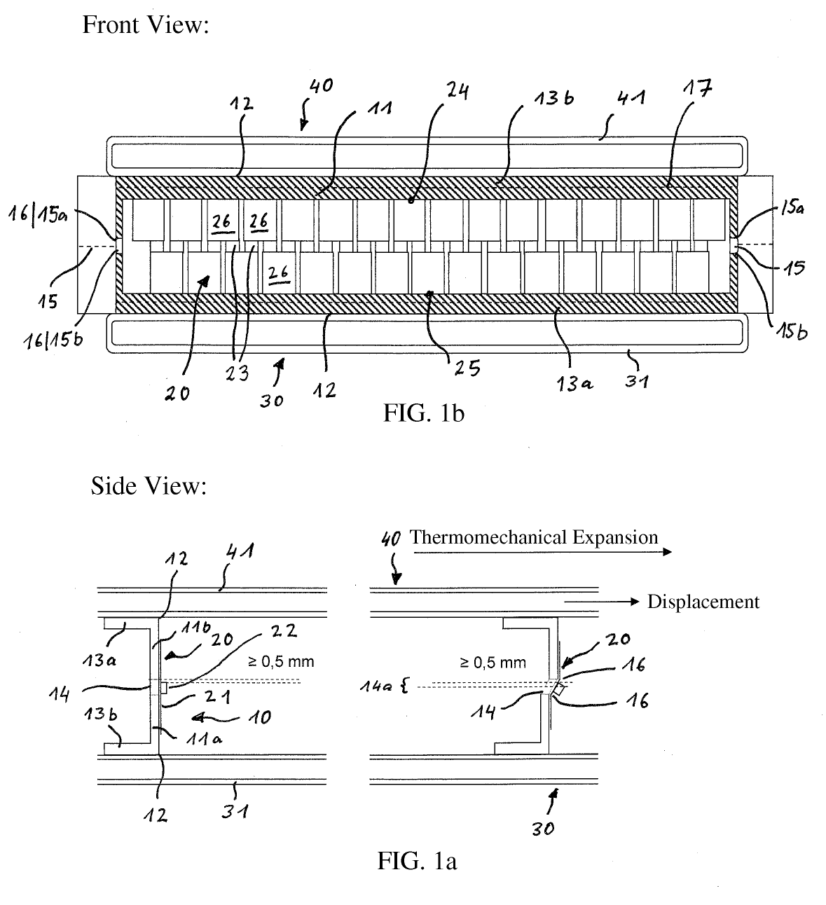

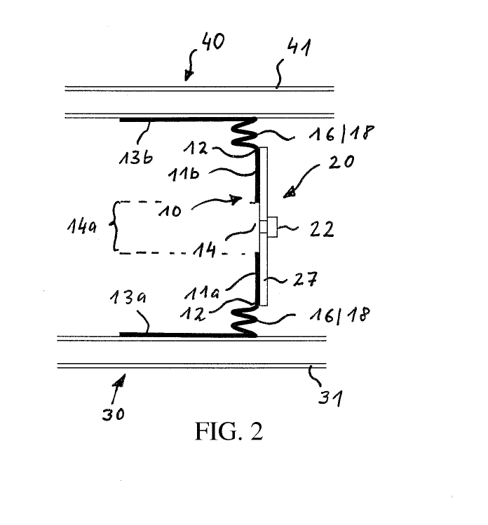

FIG. 1a shows a schematic side view of a first exemplary embodiment of a carrier element with a flexible thermoelectric thin-layer element before and after it has undergone thermomechanical expansion;

FIG. 1b shows a front view of the carrier element according to FIG. 1a;

FIG. 2 shows a schematic side view of a second exemplary embodiment of a carrier element according to the invention with a thermoelectric thin-layer element arranged on a rigid substrate;

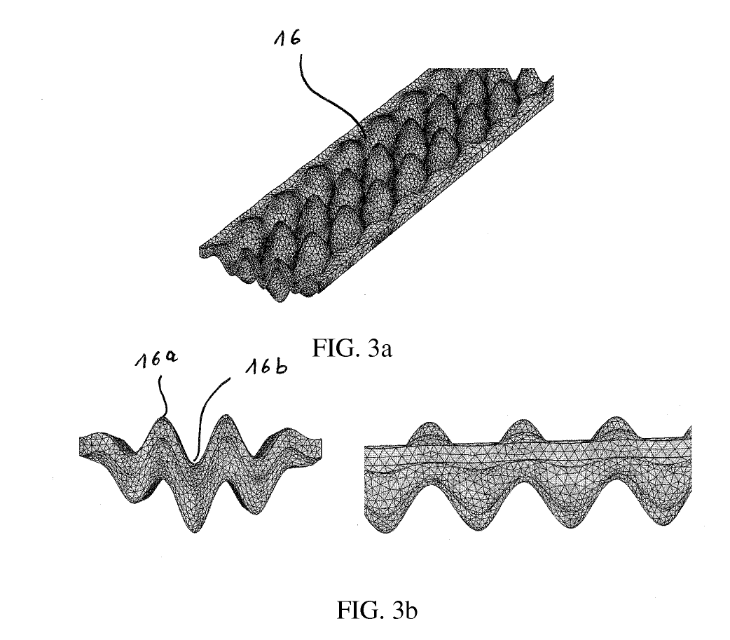

FIG. 3a shows a perspective view of a preferred embodiment of a compensating section with a nubby structure;

FIG. 3b shows side views of the nubby structure according to FIG. 3a;

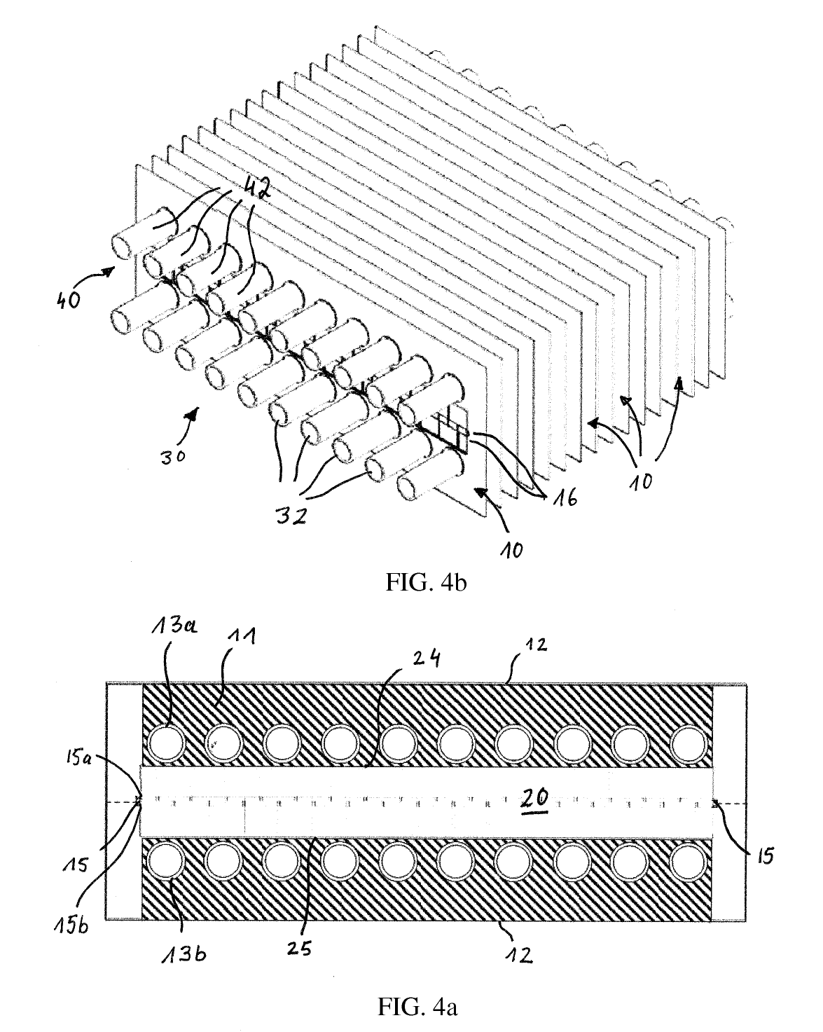

FIG. 4a shows a front view of a third exemplary embodiment of a carrier element coupled to a heat source and a heat sink, each comprising a bundle of tubes;

FIG. 4b shows a perspective view of a module built up out of several carrier elements according to FIG. 4a;

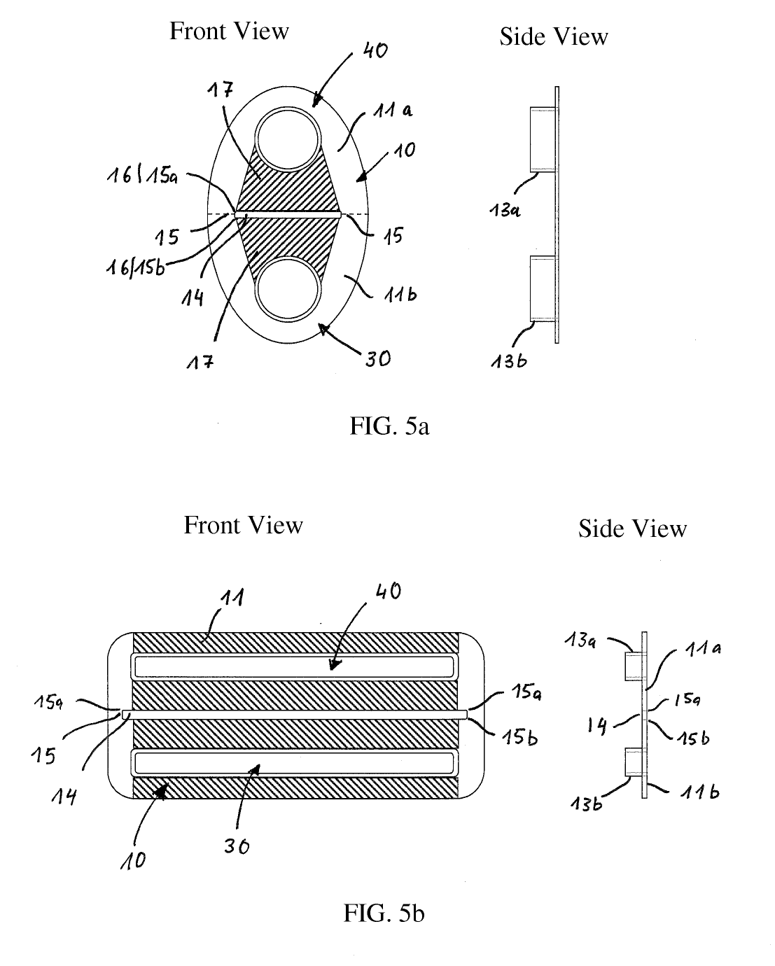

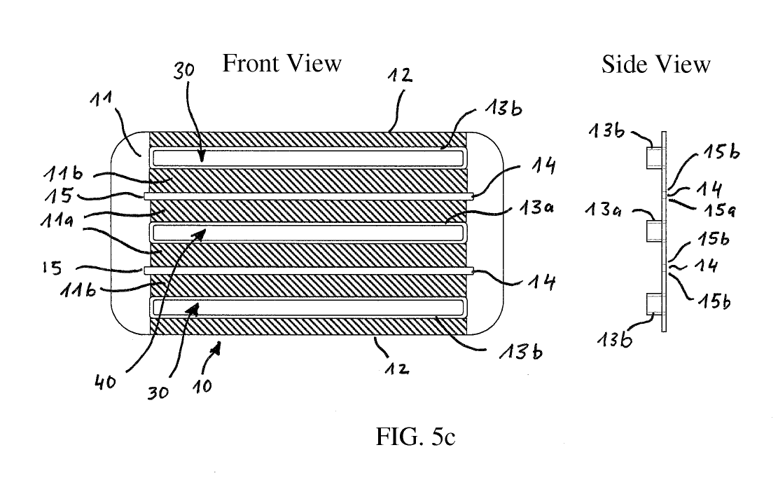

FIG. 5a shows a front view of a fourth exemplary embodiment of a carrier element with an oval contour;

FIG. 5b shows a front view of a fifth exemplary embodiment of a carrier element coupled to a heat source and a heat sink, each comprising a rectangular tube;

FIG. 5c shows a front view of a sixth exemplary embodiment of a carrier element coupled to a central heat source and two heat sinks;

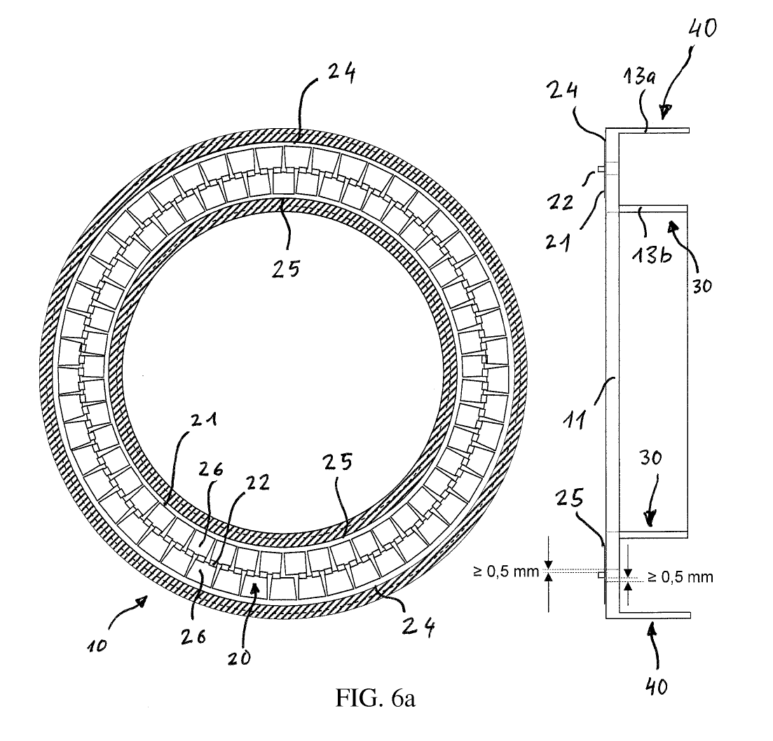

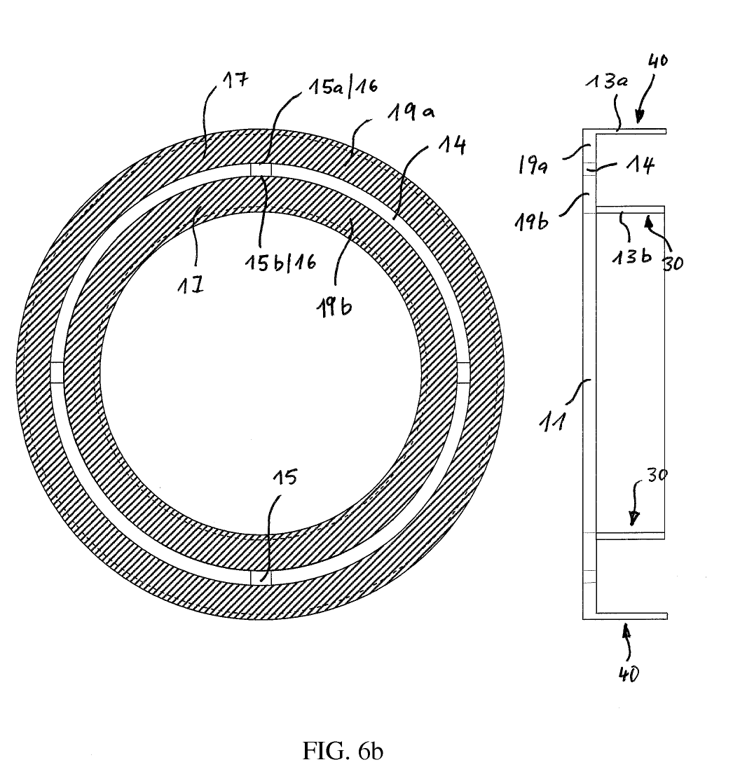

FIG. 6a shows front and side views of a seventh exemplary embodiment of a ring-shaped carrier element, on which a flexible thermoelectric thin-layer element has been mounted;

FIG. 6b shows a diagram similar to that of FIG. 6a but without the thermoelectric thin-layer element;

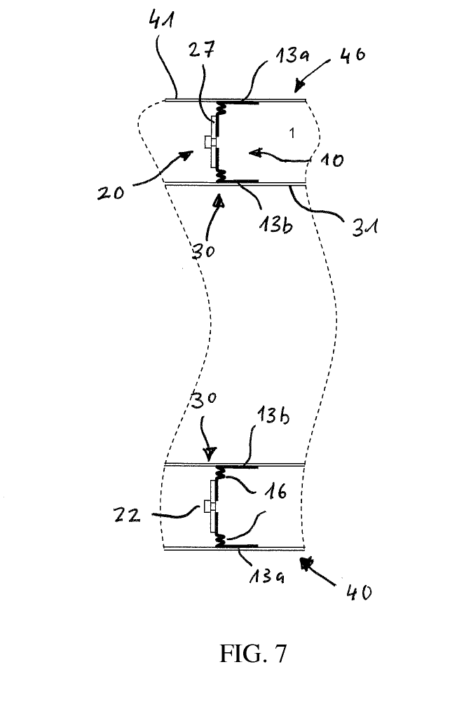

FIG. 7 shows a side view of another exemplary embodiment of a ring-shaped carrier element, on which a thermoelectric thin-layer element with a rigid substrate has been arranged;

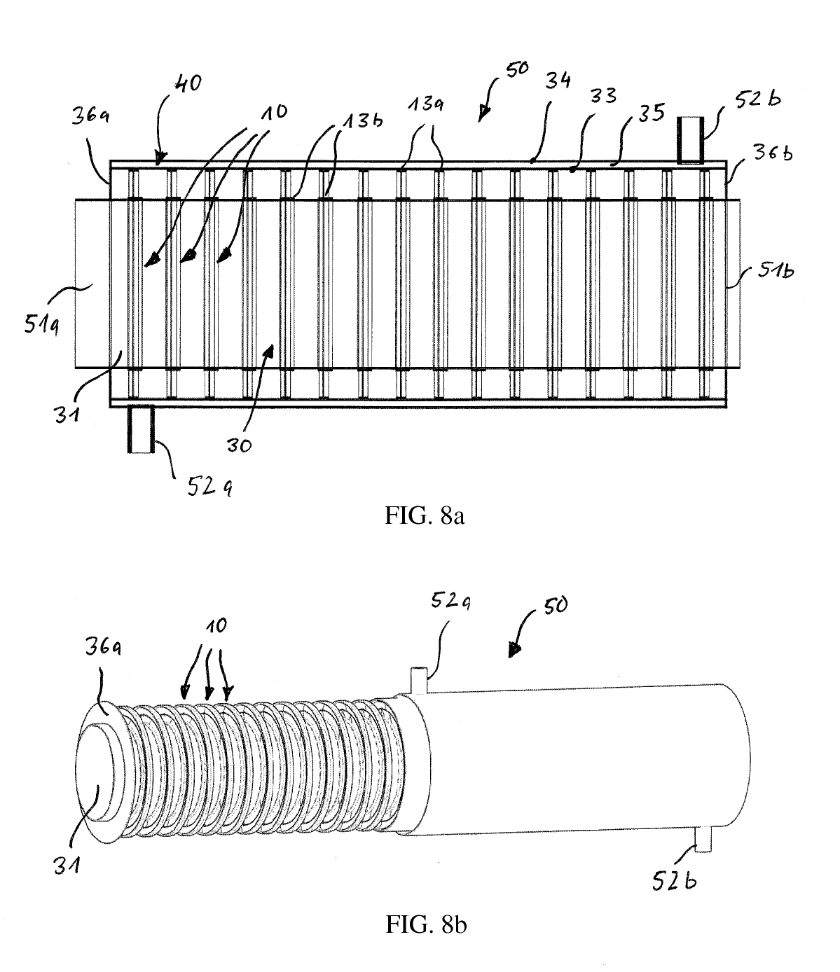

FIG. 8a shows a side view of a module built up out of several carrier elements according to FIG. 6 or FIG. 7; and

FIG. 8b shows a perspective view of the module according to FIG. 8.

FIG. 1 shows a cross-sectional side view of a carrier element 10 according to the invention, on which a thermoelectric thin-layer element 20 is arranged. The carrier element 10 is realized as a sheet-metal part, e.g. of high-grade sheet steel, and consists of an elongated rectangular plate 11, which is provided at the long edges with connecting elements 13a, b, which, in the exemplary embodiment according to FIG. 1, are configured as tabs. The tabs can be bent-over sections of the sheet-metal part. The lower connecting element 13a serves to couple the carrier element to a heat sink 30, whereas the upper connecting element 13b serves to couple the carrier element to a heat source 40. The heat sink 30 and the heat source 40 each comprise a tube 31, 41 with an elongated, rectangular cross section for a heat transfer medium, which flows through the tubes 31, 41 transversely to the plane of the plate.

As is especially clear from FIG. 1b, the cross section of the tube extends over the entire length of the strip-shaped thermoelectric thin-layer element 20 mounted on the carrier element 10. The upper connecting element 13b, configured as a tab, is permanently bonded to the bottom surface of the tube 41, and the lower connecting element 13a, also configured as a tab, is permanently bonded to the top surface of the tube 31. The permanent material bonding is achieved in particular by means of soldering. The plate 11 of the carrier element 10 is divided down the middle by a slot 14, extending parallel to the long edges 12 of the carrier element, into a first and a second part 11a, 11b, wherein the first part 11a of the plate 11 is connected in a thermally conductive manner to the heat source 40, and the second part 11b of the plate on the opposite long side of the slot 14 is connected in a thermally conductive manner to the heat sink 30.

At the side edges of the plate 11, the first part 11a and the second part 11b of the plate are connected to each other by a web 15, which bridges the slot 14. The web bases 15a on the first part 11a and the web bases 15b on the second part 11b of the plate 11 define two bending lines, serving as compensating sections 16, which are parallel to the long edges 12 of the plate 11. Compensating sections 16 of the carrier element 10 formed in this way compensate for the different thermomechanical expansions of the heat source 40 and the heat sink 30.

In the exemplary embodiment according to FIGS. 1a and 1b, the thermoelectric thin-layer element 20 comprises a flexible, strip-shaped substrate 21 in the form of, for example, a polyimide film, on which the thermoelectrically active material 22 has been applied in areas 23, which are separated from each other. This material can be applied by means of sputter deposition or some other known method for depositing layers. The separate areas 23 of thermoelectrically active material 22 are connected in an electrically conductive manner to each other, alternating between the hot side 24 and the cold side 25 of the thermoelectric thin-layer element 20, by means of metalized areas 26 to form a series circuit. The hot and cold sides 24, 25 of the thermoelectric thin-layer element 20 are parallel to the long edges 12 of the plate 11 of the carrier element 10. The hot side 24 is connected in a thermally conductive manner to the connecting element 13b for coupling to the heat source 40, and the cold side 25 is connected in a thermally conductive manner by the connecting element 13a to the heat sink 30.

To produce the thermally conductive connection, partial areas of the carrier element 10 are provided with a functional layer 17 (shown shaded in the diagram), which has a higher thermal conductivity than the carrier element 10 itself. In the exemplary embodiment, the functional layer consists of copper. The plate 11 of the carrier element 10 is provided with the functional layer 17 in the area of the first and second parts 11a, 11b of the plate 11. In the area of the webs 15, however, no functional layer is applied, because its absence reduces the parasitic heat-loss fluxes between the hot and cold sides 24, 25. The functional layer 17, furthermore, is also applied to the surfaces of the connecting elements 13a, 13b which come in contact with the tubes 31, 41 in order to achieve good thermal coupling to the heat sink 30 and heat source 14.

To mount the flexible substrate 21 of the thermoelectric thin-layer element 20 on the functional layer 17 of the carrier element, the substrate is provided with a coating, in particular a metalization, on the back, i.e., on the side facing the functional layer 17, this layer making it possible for the thermoelectric thin-layer element 20 to be soldered to the carrier element 10 carrying the functional layer 17.

It is especially easy to see in the side view of FIG. 1a that the separated areas 23 with thermoelectrically active material 22 do not extend over the entire width 14a of the slot between the hot and cold sides. In the exemplary embodiment shown here, the width of the slot is 4 mm, whereas the areas 23 with the thermoelectrically active material 22 extend over a length of only 2 mm. That the thermoelectrically active material 22 is located centrally above the slot 14 ensures that no thermoelectrically active material is present in the area of the bending lines defined by the web bases 15a, 15b. The only material present at these bending lines is the flexible substrate 21, which is not damaged by bending.

The carrier element 10 according to FIG. 1 works in the following way:

When the tube 41 of the heat source 40 is heated, the tube 41 expands relative to the tube 31 of the heat sink 30 primarily in a direction transverse to the surface of the plate 11, as illustrated in the right half of FIG. 1a. Stresses resulting from the thermomechanical expansion between the heat source 40 and the heat sink 30 are introduced into the webs 15 of the carrier element 10 and bring about a bending movement in the web bases 15a, 15b around the bending lines defined by the web bases 15a, 15b, these lines being parallel to the long edges 12. As a result of the bending around the bending lines situated in the plane of the plate, the expansions transverse to the plane of the plate can be completely absorbed by the compensating sections 16.

FIG. 2 shows an embodiment of a carrier element 10 on which a thermoelectric thin-layer element 20 with a rigid substrate 27 is mounted. The carrier element 10, consisting of copper sheet, is especially well-adapted to high-temperature applications. Like the embodiment according to FIG. 1, it comprises a plate 11 divided by a slot 14, although of much greater width 14a, into a first part 11a and a second part 11b, on which plate the rigid substrate 27 of the thermoelectric thin-layer element 20 is mounted in thermally conductive fashion by means of, for example, soldering. The connecting elements 13a, 13b for coupling to the heat sink 30 and to the heat source 40 are again realized as tabs. The upper connecting element 13b is connected to the upper long edge 12 of the plate 11 by way of a compensating section 16. The lower connecting element 13b is connected to the lower long edge 12 of the plate 11 by way of a compensating section 16. The two compensating sections 16 do not overlap the rigid substrate 27 but rather extend from the long edges 12 of the plate 11 toward the heat sink 30 or the heat source 40. The tab-shaped connecting elements 13a, 13b are permanently bonded to the heat source or heat sink 30, 40 in the same way as in the case of the exemplary embodiment according to FIG. 1.

In the exemplary embodiment according to FIG. 2, the compensating sections 16 are configured as elastic bellows 18, which extend over the entire length of the carrier element 10. Alternatively, the compensating sections 16 can comprise a two-dimensional array of elevations 16a and depressions 16b, as can be seen in FIG. 3a. A nubby structure formed in this way is capable of making compensating movements in all spatial directions.

The carrier element 1 according to FIG. 2 works in the following way:

When the tube 41 of the heat source 40 is heated, the tube 41 expands relative to the tube 31 of the heat sink 30; this expansion occurs primarily in the direction transverse to the surface of the plate 11. Stresses resulting from the thermomechanical expansion between the heat source 40 and the heat sink 30 are introduced into the elastic bellows 18 of the carrier element 10, and the deformation of the bellows compensates for the expansions of the heat source 40 and the heat sink 30. The thermoelectric thin-layer element 20 arranged on the plate 11 is not subjected to any load.

The carrier element 10 according to FIG. 4a is largely the same in structure as the carrier element 10 according to FIGS. 1a and 1b, so that, to avoid repetition, reference is made to the entire content of the discussion of those figures. There are differences with respect to the structure of the heat sink and the heat source 30, 40 and of the coupling of the carrier element to the heat source and heat sink 30, 40. The heat sink 30 and the heat source 40 each comprise a tube bundle 32, 42. The tubes of one of these bundles 32, 42 are parallel to each other and are spaced a certain distance apart, wherein each tube of the tube bundle 32, 42 is perpendicular to the plane of the plate of the carrier element 10. Connecting elements 13a, 13b, configured as sleeves and corresponding in number to the tubes of the tube bundles 32, 42, are arranged on the plate 11 of the carrier element 10, namely, on the hot and cold sides 24, 25 of the thermoelectric thin-layer element 20. The external lateral surface of each tube is preferably permanently bonded by means of a soldered joint, for example, to one of the sleeves. The coupling of the carrier element 10 over a large surface area by way of the sleeves to the tubes of the heat sink and heat source 30, 40 increases the heat flux density and thus the efficiency of the thermoelectric thin-layer element 20 in thermally conductive contact with the carrier element 10.

The carrier element 10 according to FIG. 4 works in the following way:

When the tubes of the tube bundle 42 are heated, the heat source 40 expands relative to the tubes of the tube bundle 32 of the heat sink 30; this expansion occurs primarily in the direction transverse to the surface of the plate 11. Stresses caused by the difference between the expansion of the heat source 40 and that of the heat sink 30 are introduced into the webs 15 of the carrier element 10 and cause a bending movement to occur in the web bases 15a, 15b around the bending lines defined by the web bases 15a, 15b, the bending lines being parallel to the long edges 12 of the plate 11. As a result of the bending around the bending lines situated in the plane of the plate, the expansions transverse to the plane of the plate are completely absorbed by the compensating sections 16.

FIG. 4b shows a module 50 comprising several identically configured carrier elements 10 according to FIG. 4a, wherein all of the carrier elements 10 are connected to the tube bundles 32, 42 of the heat sink 30 and heat source 40 in the same way, thus forming a stack. Each tube of the two tube bundles 32, 42 is perpendicular to the plane of the plate of the carrier elements 20.

In the exemplary embodiment of the carrier element according to FIG. 5a, the heat sink 30 and the heat source 40 each comprise only a single tube 31, 41 with a circular cross section. The contour of the carrier element 10, in contrast to the preceding exemplary embodiments, is not rectangular but oval. The connecting elements 13a, 13b, in correspondence with the exemplary embodiment according to FIG. 4a, are configured as sleeves. The oval plate is also divided by a horizontal slot 14. The first part 11a and the second part 11b of the plate are connected to each other by the two slot-bridging outer webs 15. In the same way as with the other exemplary embodiments, the web bases 15a, 15b on the first and second parts 11a, 11b of the plate 11 form the elastic compensating sections 16 of the carrier element. It can be seen in the front view of the carrier element 10 that the highly thermally conductive functional layer 17 is not present in the area of the webs 15 or of the slot 14. The functional layer is applied, however, to the inside surface of the sleeves to improve the thermal coupling to the surface of the heat source or heat sink 30, 40. In this embodiment as well, several structurally similar carrier elements 10 can be arranged in the manner of a stack, one behind the other, on the tube of the heat sink 30 and on the tube of the heat source 40.

The embodiment of the carrier element 10 according to FIG. 5b corresponds to the embodiment of the carrier element according to FIG. 4a with the difference that the heat source and the heat sink 30, 40 are not configured as tube bundles 32, 42 but rather as single tubes 31, 41 of rectangular cross section, which extend over the entire width of the thermoelectric thin-layer element 20 with its flexible substrate 21 (not shown in FIG. 5b). The compensating section 16 functions in the same way as those according to the exemplary embodiments of FIGS. 1, 4, and 5, so that, to avoid repetition, reference is made to the discussions of those figures.

The carrier element 10 according to FIG. 5c is suitable for the arrangement of two strip-shaped, flexible thermoelectric thin-layer elements 20 (not shown in FIG. 5c). Arranged centrally in, and extending over the length of, the carrier element 10, a connecting element 13a, configured as an elongated, rectangular sleeve for coupling the carrier element to the heat source 40, extends through a central tube 41 of rectangular cross section.

In the area of the long edges 12 of the carrier element, two connecting elements 13b, configured as elongated rectangular sleeves, extend in the same direction as the connecting element 13a and serve to couple the carrier element in each case to a tube 31 of rectangular cross section of the heat sink 30. Between the connecting element 13a and the two connecting elements 13b, the plate 11 of the carrier element is divided in each case by a slot 14, wherein a first part 11a of the plate 11 is in thermally conductive contact on a long side of the slot 14 with the heat source 40, and a second part 11b of the plate 11 is in thermally conductive contact on the opposite side of each slot 14 with one of the two tubes 31 of the heat sink 30. On both sides of the two slots 14 are connecting webs 15, the web bases 15a, 15b of which represent the compensating sections 16 of the carrier element between the coupling to the heat source 40 and the coupling to the heat sinks 30

FIGS. 6a and 6b show an exemplary embodiment of a carrier element 10 with a ring-shaped plate 11, on which a flexible thermoelectric thin-layer element 20 is arranged in a ring-like manner. As can be seen especially clearly in FIG. 6b, the ring-shaped plate 11 is divided by a circular slot 14 into two concentric circular rings 19a, 19b. The circular rings 19a, 19b are connected to each other by four webs 15, which bridge the slot 14 and are offset from each other by 90°. On the outer circumference of the ring-shaped plate 11, a connecting element 13a, which passes around the entire circumference, is provided to couple the carrier element to a heat source 40. On the inner circumference of the ring-shaped plate, a connecting element 13b, which passes around the entire circumference, is arranged to couple the carrier element to a heat sink 30. The connecting elements 13a, 13b, which are configured as tabs, extend at a right angle to the surface of the plate. The compensating sections 16 of the carrier element 10 are located in the web bases 15a, 15b of the connecting webs. The functional layer 17 of highly thermally conductive material is applied to the outward-facing, ring-shaped surface of the circular rings 19a, 19b, i.e., the surface which comes in contact with the thermoelectric thin-layer element. To avoid parasitic heat flows from the hot side 24 to the cold side 25, the surfaces of the webs 15 are not provided with the functional layer 17. In addition, the functional layer 17 is also present on the surface areas of the connecting elements 13a, 13b, which serve to couple the carrier element to the heat source 40 and to the heat sink 30.

The ring-shaped carrier element 10 makes it possible to arrange the heat source 40 and the heat sink 30 coaxially, as will be explained below on the basis of FIG. 8. The different degrees of expansion of the heat source 40 and the heat sink 30 parallel to the direction in which the connecting elements 13a, 13b extend are compensated by the bending which occurs in the web bases 15a, 15b of the webs 15. The arrangement of the thermoelectrically active materials 22 of the flexible thermoelectric thin-layer element 20 relative to the slot 14 is similar to that shown in FIGS. 1, 4, and 5.

The exemplary embodiment according to FIG. 7 differs from the ring-shaped carrier element 10 according to FIGS. 6a and 6b in that the thermoelectric thin-layer element 20 applied to the carrier element 10 comprises a rigid substrate 27. The arrangement of the compensating sections 16 and of the connecting elements 13a, 13b is the same as that in the configuration according to FIG. 2, so that reference can be made to the complete content of that discussion.

Connecting sections 13a, 13b of the carrier element 11 are connected to coaxially arranged tubes of a heat sink 30 and a heat source 40. The carrier element 10 consists in particular of copper sheet. The connecting elements 13a, 13b are permanently bonded to the tubes 31, 41 of the heat sink and heat source 30, 40 by soldering, adhesive bonding, or welding. The carrier element according to FIG. 7 is especially adapted to applications in the temperature range above 250° C., because the rigid substrate 27 can also consist of high temperature-resistant material.

FIG. 8 shows a module 50 comprising several identically configured carrier elements 10 embodied as in to FIG. 6 or FIG. 7. The carrier elements 10 are arranged one behind the other, spaced uniformly apart, on a tube 31 of the heat sink 30 and are permanently bonded to the lateral surface of the tube 31 by means of the connecting elements 13b. The connecting elements 13a arranged on the outer circumference of the circular carrier elements are arranged on an inner jacket tube 33 of the heat source 40. Cover plates 36a, 36b close off the annular space 35 at the ends. In the area of the two end surfaces 51a, 51b of the module 50, connector nozzles 52a, 52b are arranged on the outer jacket tube 34 of the heat source 40. A thermal transfer medium is conducted into the annular space 35 via the connector nozzle 52a and leaves the annular space via the connector nozzle 52b.

### LIST OF REFERENCE NUMBERS

No. Description
10 carrier element
11 plate
11a first part
11b second part
12 long edges
13a, b connecting element
14 slot
14a width of slot
15 web
15a web base
15b web base
16 compensating section
16a elevations
16b depressions
17 functional layer
18 elastic bellows
19a, b circular rings
20 thermoelectric thin-layer element
21 flexible substrate
22 thermoelectrically active material
23 separated areas
24 hot side
25 cold side
26 metalized areas
27 rigid substrate
30 heat sink
31 tube
32 tube bundle
33 jacket tube, inner
34 jacket tube, outer
35 annular space
36a, b cover plates
40 heat source
41 tube
42 tube bundle
50 module
51a, b end surfaces
52a, b connector nozzles

1.-27. (canceled)

28. A carrier element, comprising:
a coupling to a heat source; and
a coupling to a heat sink;
a thermoelectric thin-layer element with a hot side and a cold side arranged between the coupling to the heat source and the coupling to the heat sink, wherein the hot side is connected in thermally conductive fashion to the coupling to the heat source, and the cold side is connected in thermally conductive fashion to the coupling to the heat sink;
a plate on which the thermoelectric thin-layer element is arranged, the plate having connecting elements serving as the coupling to the heat source and the coupling to the heat sink; and
at least one elastic and/or flexible compensating section arranged between the coupling to the heat source and the coupling to the heat sink in such a way that the compensating section compensates for a difference between an expansion of the heat source and an expansion of the heat sink by a change of shape of the compensating section.

29. The carrier element according to claim 28, wherein the compensating section comprises linear-elastic behavior.

30. The carrier element according to claim 28, wherein the compensating section comprises at least one of elevations and depressions.

31. The carrier element according to claim 28, wherein the compensating section comprises a nubby structure.

32. The carrier element according to claim 28, wherein the compensating section is configured as an elastic bellows.

33. The carrier element according to claim 28, wherein the compensating section consists of a soft material.

34. The carrier element according to claim 28, wherein the thermoelectric thin-layer element comprises a substrate and a thermoelectrically active material applied to the substrate.

35. The carrier element according to claim 34, wherein areas of the thermoelectrically active material, which are separated from each other alternating between the hot and cold sides of the thin-layer element, are connected electrically to each other by metalized areas.

36. The carrier element according to claim 34, wherein the substrate comprises a flexible material.

37. The carrier element according to claim 34, wherein the substrate comprises a rigid material.

38. The carrier element according to claim 28, wherein the substrate is arranged on the surface of the carrier element in such a way that the thermoelectrically active material is not arranged in an area above a surface of the compensating section.

39. The carrier element according to claim 28, wherein both the coupling to the heat source and the coupling to the heat sink are permanently bonded couplings.

40. The carrier element according to claim 28, wherein the connecting elements are configured as sleeves and extend in a direction perpendicular to a plane of the plate.

41. The carrier element according to claim 28, wherein the connecting elements are configured as tabs, which extend in particular in a direction perpendicular to a plane of the plate.

42. The carrier element according to claim 28, further comprising a functional layer, which has higher thermal conductivity than the material of the carrier element.

43. The carrier element according to claim 28, wherein the plate is divided by at least one slot into a first part of the plate that is in thermally conductive contact along one of the long sides of the slot with the heat source, and a second part of the plate that is in thermally conductive contact on the opposite long side of the slot with the heat sink.

44. The carrier element according to claim 43, wherein the first and second parts of the plate are connected to each other by at least one web, which bridges the slot.

45. The carrier element according to claim 44, wherein a base of each web on at least one of the first part and the second part of the plate is elastic and is configured as the compensating section.

46. The carrier element according to claim 45, wherein the thermoelectrically active material of the thin-layer element is located exclusively in an area above the slot relative to a surface of the plate.

47. The carrier element according to claim 43, wherein the plate is ring-shaped and is divided by the slot into two concentric circular rings.

48. The carrier element according to claim 28, wherein the plate is rectangular.

49. The carrier element according to claim 28, further comprising at least one of the heat sink and the heat source, the at least one of the heat sink and the heat source comprising a tube for conducting a heat transfer medium, the carrier element being coupled to the tube.

50. The carrier element according to claim 49, wherein the tube extends in a direction perpendicular to the plane of the plate of the carrier element.

51. A module, comprising a plurality of identically configured carrier elements, each of the carrier elements according to claim 28, and at least one of a common heat source and a common heat sink to which all of the carrier elements are coupled.

52. The module according to claim 51, wherein the at least one of the common heat source and the common heat sink comprises at least one tube through which a heat transfer medium is conducted, and all of the carrier elements are coupled to the at least one tube.

53. The module according to claim 42, wherein the at least one tube extends in a direction transverse to a surface of each carrier element.
